(19) United States
(12) Patent Application Publication
(10) Pub. No.: US 2018/0028037 A1
(43) Pub. Date: Feb. 1, 2018

(54) SCRUBBING ARTICLE AND METHOD OF MAKING SAME

(71) Applicant: 3M INNOVATIVE PROPERTIES COMPANY, St. Paul, MN (US)

(72) Inventors: Paul N. Daveloose, Maplewood, MN (US); Matthew S. Cole, Woodbury, MN (US); Ibrahim S. Gunes, Minneapolis, MN (US); Irem Bolukbasi, St. Paul, MN (US); Daniel J. O'Neal, St. Paul, MN (US)

(21) Appl. No.: 15/548,712

(22) PCT Filed: Feb. 4, 2016
(86) PCT No.: PCT/US2016/016530

§ 371 Date: Aug. 3, 2017

Related U.S. Application Data
(60) Provisional application No. 62/121,766, filed on Feb. 27, 2015.

(51) Int. Cl. A47L 13/17; C08J 7/18; C23C 16/56; B24D 11/00; B24D 3/00; A47L 17/08; C11D 17/04

(52) U.S. Cl. CPC A47L 13/17; A47L 17/08; C08J 7/18; C11D 17/049; B24D 11/001; B24D 3/008; C23C 16/56; C08J 2309/08; C08J 2367/02

(57) ABSTRACT

A scrubbing article (10) including a substrate (12) and an e-beam treated texture layer (14) on a surface of the substrate (12). The substrate (12) comprises a material suitable for use as a scrubbing article. The e-beam treated texture layer (14) is a resin-based material forming a textured abrasive layer (14) on the surface of the substrate (12).

### BACKGROUND

The present disclosure relates to a scrubbing article having a textured surface. More particularly, the present disclosure relates to a scrubbing article having an e-beam treated texture layer to provide the scrubbing article with enhanced surface treating capabilities. A variety of cleaning articles in the form of pads and wipes have been developed and made commercially available for household and industrial use. Consumers oftentimes desire to use the articles for cleaning or surface treating tasks requiring scrubbing which in turn may include various degrees of abrading and/or scouring. For example, it can be difficult, if not impossible, to remove dried food from a countertop using an inherently soft article. Conversely, however, consumers strongly prefer that the article not be overly rigid. In some cases, consumers thus desire that the article be drapable for ease of use. Furthermore, consumers often desire a scrubbing pad or wipe that is not overly abrasive on relatively soft or easily scratched surfaces. In addition, consumers often find cleaning articles that are pre-loaded with a cleaning/disinfecting/sanitizing chemical or chemicals to be extremely useful and convenient.

Scrubbing articles have been developed to address some of the above-identified desires and concerns. For example, U.S. Pat. No. 7,829,478 to Johnson et al., describes a scrubbing wipe article including a nonwoven substrate and a texture layer. The texture layer is a non-crosslinked, abrasive resin-based material that is printed onto at least one surface of the nonwoven substrate. Johnson et al. teach that the texture layer composition is printed onto the substrate and then caused to coalesce to bond the composition to the substrate. Johnson et al. further describe that the resin constituent does not crosslink as part of the coalescing step and that coalescing represents a distinct advantage over other scrubbing wipe article forming techniques in which a lengthy curing period is required to achieve a sufficient hardness value. The scrubbing wipe article of Johnson et al. can be used “dry” or can be loaded with a chemical solution.

U.S. Patent App. Pub. No 2006/0286884 to Thioliere et al. describes a wiping article comprising a liquid-absorbent web material and abrasive areas comprising cured binder material disposed on a surface of the web. The web material may include woven, knitted and non-woven materials. Non-woven materials may include dry-laid, wet-laid and spun-bonded materials. Suitable binder materials are disclosed that can be cured by heating, cooling or ultraviolet light.

U.S. Patent App. Pub. No. 2007/0212965 to Smith et al. describes a flexible scrubbing material that combines at least two discrete components, one being a continuous flexible substrate and one a discontinuous abrasive layer affixed to the flexible substrate. The abrasive layer is a set of plates formed from a material different than the continuous flexible substrate. The plate material is a printable material that subsequently solidifies, such as epoxy. Smith et al. teach that the abrasive plates can be formed from a solidified material such as ultraviolet or thermally curable polymeric materials with or without abrasive particles embedded inside. Smith et al. further describe a technique for printing the plates onto the substrates such as conventional screen-printing, UV etching and roller-printing. An adhesive is sprayed on the fabric prior to application of the plates.

Various materials and material compositions may be used to form a textured surface layer of a scrubbing material. Further, texture layers may be deposited or formed on a substrate using a variety of methods. Some methods include printing, coating (e.g., roll, spray etc.), embossing, micro-replication, or etching (e.g., laser, mechanical, etc.) a material or materials onto a substrate to form a textured surface (also referred to herein as an “abrasive surface”) having various degrees of abrasion. Crosslinking of the materials (i.e., abrasives) formed on the substrate can significantly improve a variety of properties of the deposited or formed abrasives, including the durability, hardness, tensile and impact strength, high-heat properties, solvent and chemical resistance, abrasion resistance, and environmental stress crack resistance.

Electron beam (e-beam) radiation can be used to effect sterilization, polymerization, degradation and crosslinking of materials. E-beam treatment is rapid, clean, and can be a relatively cost-effective method for crosslinking and/or polymerizing materials. Notably, e-beam treatment does not include the disadvantages of other crosslinking methods such as thermal, UV and gamma radiation. For example, e-beam treatment does not require additives nor does it include materials that can leech out of the cured composition and can take place at both ambient and sub-ambient temperatures. Further, e-beam treatment is energy efficient and requires a minimal amount of beam exposure time which in turns aids in faster processing times as compared to other curing methods. Further still, the radiation in e-beam treatment can be described as a relatively low energy, high dose rate radiation which in turn avoids long exposure time of lower dose rate (e.g., gamma, x-ray) radiation, and deposits the energy into thinner layers more efficiently than high energy (e.g., gamma) radiation.

As described above, improvements in the properties of the scrubbing surface (e.g., texture layer) of a scrubbing article may be beneficial and therefore desirable. Likewise as described above, improvements to the manufacturing processes of scrubbing articles can be advantageous. A need therefore exists for a scrubbing article that includes the benefits and advantages of an e-beam treated (e.g., e-beam polymerized or crosslinked or both) textured surface for scrubbing.

### SUMMARY

Aspects of the present disclosure relate to a scrubbing article. The scrubbing article comprises a substrate including any of a woven, knitted, non-woven, fabric, foam, film and sponge material or combinations thereof and an e-beam treated texture layer formed on a surface of the substrate.

The substrate may be single or multi-layer. The e-beam treated texture layer may be e-beam polymerized, e-beam crosslinked, or both, according to embodiments. The texture layer may define a plurality of randomly distributed texturings or may define a pattern that can include a plurality of discrete segments. The discrete segments may include at least one of series of unconnected lines, dots or images. In some embodiments the e-beam treated texture layer extends at least 500 microns outwardly from the surface of the substrate. In still further embodiments the e-beam treated texture layer is characterized by the absence of a thermal and a photo-initiating component. The texture layer may be non-ionic, anionic or cationic and in some embodiments a chemical solution is absorbed into the substrate. The texture layer may have a hardness that is greater than a hardness of the substrate and in this manner the article may be flexible or drapable while the texture layer is relatively rigid in comparison. These characteristics may impart unique cleaning and scrubbing attributes to the scrubbing articles according to the disclosure.

Other aspects of the present disclosure relate to a method of manufacturing a scrubbing article. Some methods include transferring a resin composition onto a surface of a substrate to form an e-beam treatable texture layer on the surface and thereby form an interim textured scrubbing article, then treating the interim textured scrubbing article with e-beam radiation to form an e-beam treated texture layer on the substrate surface. The substrate can include various materials including woven, nonwoven, fabric, foam, film and sponge materials or combinations thereof. E-beam treatment involves exposing the article (the substrate with abrasive resin provided thereon) to electron beam radiation. E-beam treatment can effect crosslinking and/or polymerization of the resin composition. In this manner, an e-beam crosslinked and/or e-beam polymerized texture layer is formed on the substrate. The e-beam treated texture layer may have a relative hardness equal to or greater than a hardness of the substrate. Further, the e-beam treatable texture layer and e-beam treated texture layer may each define a pattern on the substrate. Some methods of manufacture may be characterized by the absence of a thermal and/or UV crosslinking or polymerization step.

This can be especially advantageous in that significantly less time is needed to crosslink (or polymerize) materials via use of an electron beam as compared to thermal or UV treatments and no undesirable initiators are required to effect the crosslinking or polymerization reactions desired. Methods according to the disclosure may include, prior to the e-beam radiation step, exposing the interim textured scrubbing article to heat to evaporate an amount of water from the e-beam treatable texture layer. The heat exposure time may be minimal, such as on the order of three minutes or less.

Other methods of manufacture according to the disclosure include manufacture of a texture layer for a scrubbing article including depositing an e-beam crosslinkable composition onto a surface of a substrate to form an e-beam crosslinkable abrasive layer and e-beam crosslinking the abrasive layer by exposing it to e-beam radiation to form an e-beam crosslinked abrasive layer wherein the substrate has a flexibility greater than a flexibility of the e-beam crosslinked abrasive layer.

### BRIEF DESCRIPTION OF THE DRAWINGS

FIG. 1 is a perspective view of an exemplary scrubbing article in accordance with the present disclosure;

FIG. 1A is an enlarged plan view of a portion of the surface of the scrubbing article of FIG. 1;

FIG. 2 is an enlarged, cross-sectional view of a portion of the article of FIG. 1 along the lines 2-2, shown in FIG. 1;

FIG. 3 is an enlarged, cross-sectional view of the article portion of FIG. 2 being applied to a surface;

FIG. 4 is a simplified illustration of a method of manufacture in accordance with an embodiment of the present disclosure; and

FIGS. 5A-5B are top views of alternative embodiments of a scrubbing article in accordance with the present disclosure.

### DETAILED DESCRIPTION

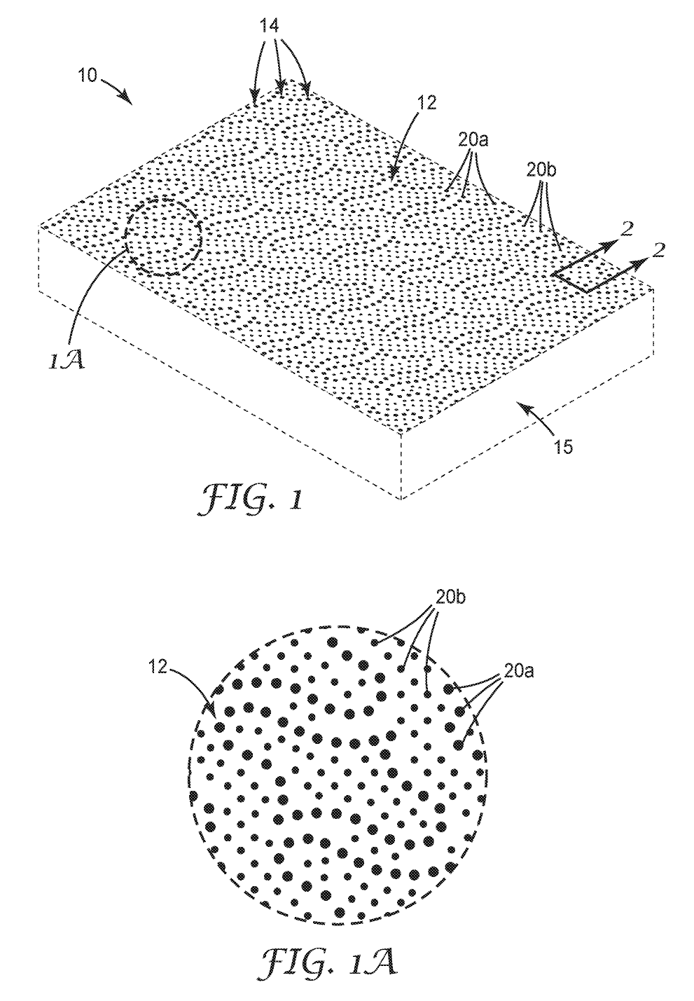

FIG. 1 illustrates an embodiment of a scrubbing article 10 in accordance with the present disclosure. Scrubbing article 10 may be described as a consumer cleaning or scrubbing article 10. As used throughout this Specification, the term “consumer” is in reference to any household, cosmetic, industrial, hospital or food industry applications and the like of the article 10. Certain embodiments can be used as floor pads or hand pads, for example. Further as used throughout this Specification, the term “scrubbing” is used to describe surface treating and may include cleaning, abrading and/or scouring, including various levels or degrees of abrading and/or scouring action (e.g., heavy duty, non-scratch, etc.). The article 10 comprises a substrate 12 and a texture layer 14 (referenced generally in FIG. 1). The substrate 12 and the texture layer 14 can comprise a variety of different materials as described further below. Regardless, the texture layer 14 is characterized as including an abrasive composition that is formed on and perhaps at least partially penetrates the substrate 12 and is exposed to electron beam radiation (e-beam treated) to form an e-beam treated (e-beam crosslinked and/or e-beam polymerized) texture layer 14, as will be described more fully below. It is to be understood that where an “e-beam crosslinkable or e-beam crosslinked” material or composition is disclosed throughout this Specification, likewise an “e-beam polymerizable or e-beam polymerized” material or composition may be included (added) or substituted. In other words, the present disclosure encompasses texture layer 14 compositions that may include e-beam polymerized/polymerizable materials (e.g., monomers) or e-beam crosslinked/crosslinkable materials (e.g., multifunctional monomers, polymers), or may include both, whether or not indication is specifically made to these alternative texture layer composition possibilities. As a point of reference, FIG. 1 further reflects that the scrubbing article 10 can optionally include one or more complimentary bodies 15 (drawn in phantom) to which the substrate 12 is attached. The substrate 12 and the auxiliary body 15 can be formed of differing materials (e.g., the substrate 12 is a nonwoven material and the auxiliary body 15 is a sponge). In other embodiments, the auxiliary body 15 is omitted.

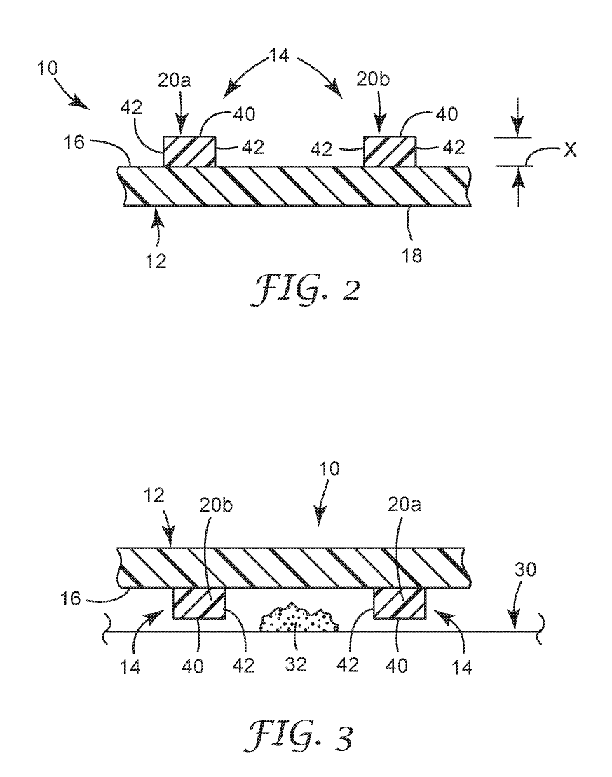

With additional reference to FIG. 2, the substrate 12 defines first and second opposing surfaces 16, 18. For purposes of illustration, thicknesses of the substrate 12 and the texture layer 14 may be exaggerated or understated in FIG. 2. The texture layer 14 can be formed on one or both of the substrate surfaces 16, 18. In some embodiments, the scrubbing article 10 further includes a chemical solution (not shown) loaded into, or absorbed by, the substrate 12. Applicable chemical solutions are likewise described in greater detail below. The texture layer 14 may be configured to accommodate a wide variety of chemical solutions including those that are neutral, cationic, or anionic. Further, the scrubbing article 10 is equally useful without a chemical solution.

Compositions of the substrate 12 and the texture layer 14, as well as processing thereof, are provided below. The scrubbing article 10 may be described as providing a “scrubbiness” attribute. The term “scrubbiness” is in reference to an ability to abrade or remove a relatively small, undesirable item otherwise affixed to a surface as the article is moved back and forth over the item. A substrate can be given a scrubbiness characteristic not only by forming a hardened scrubbing material on the substrate's surface (i.e., harder than the substrate itself), but also and perhaps more prominently via the extent to which the so-formed material extends from or beyond the substrate surface in conjunction with side-to-side spacing between individual sections of the scrubbing material. The texture layer of the present disclosure provides and uniquely satisfies both of these scrubbiness requirements.

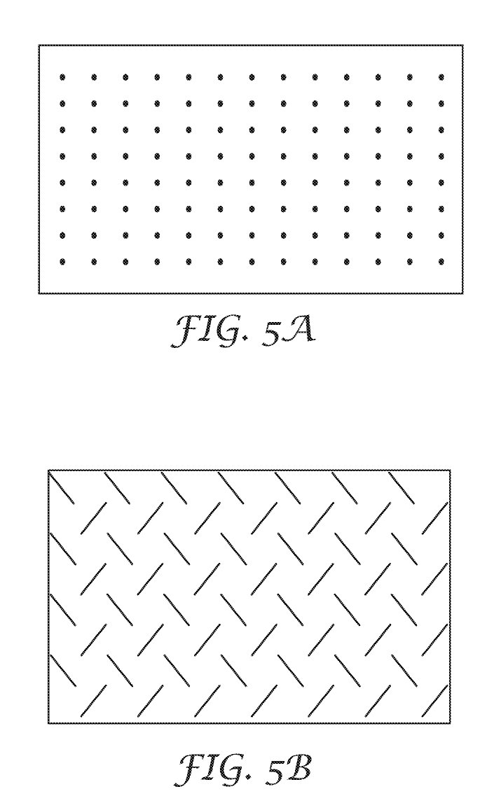

By way of further explanation, the texture layer 14 defines a plurality of discrete portions (e.g., the various dot-like portions shown in FIG. 1 and referenced generally at 20a, 20b). Discrete portions 20a, 20b may form a randomly textured surface or may form a pattern on the substrate surface 16. Further, discrete portions (e.g., 20a, 20b) may comprise varying relative sizes or may be substantially uniform in size. For instance, and as illustrated in FIG. 1A, dots 20a are relatively larger than dots 20b. Further, discrete portions (e.g., 20a, 20b) may extend or project outwardly from the surface 16 at substantially uniform distances or, alternatively, may extend or project outwardly from the surface 16 at varying distances (i.e. the discrete portions 20a, 20b can have similar or varying heights with respect to the surface 16). In some embodiments, discrete portions (e.g., 20a, 20b) may extend to any distance in a range of about 10 to about 500 microns outwardly from the surface 16. In other embodiments, discrete portions (e.g., 20a, 20b) may extend to any distance in a range of about 10 to about 20 microns outwardly from the surface 16. In still further embodiments, discrete portions (e.g., 20a, 20b) may extend to a distance of 500 microns or less outwardly from the surface 16. An advantage of the e-beam crosslinkable compositions making up texture layer 14 described herein is that e-beam crosslinking can more effectively penetrate thicker texture layer compositions than for example may be possible via UV or thermal curing. In addition, thermal curing may be able to achieve penetration or cure of a thicker (e.g., over 100 microns) composition, however, the process of thermal curing thicker compositions can add significant time to the curing process as discussed more fully below. Regardless, a variety of texturings and/or patterns can be provided on the substrate 12. Alternative exemplary embodiments of patterns useful with the present disclosure are shown in FIGS. 5A-5B.

Regardless of the pattern design and/or extension distance of portions (e.g., 20a, 20b) from the surface 16, during a scrubbing application, a user (not shown) will normally position the scrubbing article 10 such that the texture layer 14 is facing the surface to be scrubbed. An example of this orientation is provided in FIG. 3 whereby the scrubbing article 10 is positioned to clean or otherwise treat a surface 30. As should be understood, the surface 30 to be cleaned is application specific, and can be relatively hard (e.g., a table top or cooking pan) or relatively soft (e.g., human skin, polymeric baking vessels, etc.). Regardless, in the exemplary embodiment of FIG. 3, the surface 30 to be scrubbed may have a mass 32 that is undesirably affixed thereto. Again, the mass 32 will be unique to the particular scrubbing application, but includes matters such as dirt, dried food, dried blood, etc. The scrubbing article 10 of the present disclosure facilitates scrubbing removal of the mass 32 as a user repeatedly forces the texture layer 14 (or a portion or section thereof) back and forth across the mass 32. Each section (for example, the portions 20a, 20b) of the texture layer 14 must be sufficiently hard to either abrade or entirely remove the mass 32 during the scrubbing motion. In addition, the texture layer 14 must extend an appreciable distance from the substrate surface 16 to ensure intimate surface interaction with the mass 32 along not only an outer most surface 40, but along sides 42 as well. Portions 20a, 20b, while depicted as having uniform, sharp corners or edges (at the intersection of surface 40 and sides 42), may likewise or instead have rounded edges or corners or may be non-uniform in cross-section. What is important is that the extension of the texture layer is such that the desired scrubbiness is achieved. Notably, many cleaning wipes incorporating a blown fiber “scrubbing” or texture layer provide only a minimal thickness or extension relative to the substrate surface, likely giving rise to a less than desirable scrubbiness characteristic. Further, it is preferred that the discrete portions (for example, the portions 20a, 20b) provided by the texture layer 14 of the present disclosure be sufficiently spaced from one another to ensure intimate contact between the mass 32 and the sidewall 42 of the particular texture layer portion 20a, 20b during a cleaning operation. Further still, it is desirable that the texture layer 14 has abrasion resistance such that the composition forming the texture layer 14 remains substantially intact on the substrate 12 during and after the article 10 is used to scrub a surface 30. Importantly, the e-beam treated texture layer 14 of the present disclosure may be configured to have a relative hardness at least equal to or greater than the hardness of the substrate 12 to which the layer is imparted, as briefly referred to above. Stated otherwise, the local hardness of the texture layer portions (e.g., 20a, 20b) or overall texture layer 14 is equal to or greater than the hardness of the entire article 10, or the “global hardness”. Article 10 may thus be defined as having global flexibility, since the substrate 12 is softer or more flexible in relation to the harder, less flexible abrasive/texture layer 14. Hardness of a texture composition 14 after having been formed on a substrate as well as hardness of a substrate (for comparison) can be achieved in a number of ways. For example, hardness of a material can be established by determining the Rockwell indentation hardness, such as described in ASTM E18-14a: Standard Test Methods for Rockwell Hardness of Metallic Materials; by determining Knoop and Vickers hardness, such as described in ASTM E384-10: Standard Test Method for Knoop and Vickers Hardness of Materials; by determining the durometer hardness, such as described in ASTM D2240-05: Standard Test Method for Rubber Property-Durometer Hardness, or by determining the Brinell hardness, such as described in ASTM E10-14: Standard Test Method for Brinell Hardness of Metallic Materials. An article having these characteristics is uniquely useful as a scrubbing article in that the article 10 is sufficiently flexible to allow a user to make contact in, on and about a variety of objects to be scrubbed, while the hardness of the abrasive layer 14 provides the desired scrubbing performance. The above features are readily achieved via the textured layer and e-beam treatments of the present disclosure as described below.

### Substrates

The substrate 12 may be formed from a variety of materials and in a variety of forms. Any substrate material or combination of materials suitable for use as a consumer scrubbing article can be used including, without limitation, various woven, knitted, non-woven, foam, sponge and film materials. The materials and forms of the substrate 12 can be selected to provide varying ranges of desired properties, such as extensibility, elasticity, durability, flexibility, printability, etc., that are particularly suited to a given scrubbing task and/or are particularly suited to depositing or forming of a composition thereon. As indicated, materials useful for substrate 12 may be selected to have durability properties in a wide range. For example, the durability of materials suitable for use in scrubbing articles is often categorized as “disposable” (meaning that an article formed from the material is intended to be discarded immediately after use), “semi-disposable” (meaning that an article formed from the material can be washed and re-used a limited number of times), or “reusable” (meaning that an article formed from the material is intended to be washed and re-used). Also as indicated above, materials may be selected based upon their flexibility. Depending upon the application, consumers may prefer a relatively flexible, supple or drapable scrubbing article, whereas in other applications, consumers prefer a relatively more rigid article that still maintains some degree of flexibility. In applications where a relatively more supple scrubbing article is preferred (e.g., drapable), providing a more flexible substrate 12 allows the user to readily fold, squeeze, or otherwise manipulate the scrubbing article 10 in a manner most appropriate for the particular scrubbing task. The desired suppleness of the substrate 12 is best described with reference to a dry basis weight thereof. The nonwoven substrate 12 of the present disclosure has a dry basis weight of less than about 300 g/m², but preferably greater than about 30 g/m². In other embodiments, the nonwoven substrate 12 has a dry basis weight of less than about 200 g/m². Alternatively, the suppleness of the nonwoven substrate 12 can be expressed in terms of drapability. “Drapability” is defined as the inherent ability to conform to an irregular or non-flat surface. Drapability or “drape” is measured using INDA standard for “Handle-O-Meter Stiffness of Nonwoven Fabrics” IST 90.3 (95). With this in mind, the nonwoven substrate 12 preferably has a drapability value of less than about 250. In scrubbing applications where a relatively stiffer, yet still flexible substrate is desired, substrate 12 may be formed of a composition and into a form that substantially holds its shape both when held by a user or when placed on an irregular surface.

Some exemplary substrates 12 will now be described, however, a wide variety of materials may be used for substrate 12, as noted above. Exemplary fabrics useful with the present disclosure include a knitted fabric prepared from 82% poly(ethylene terephthalate) and 18% polyamide 6 fibers having a thickness in a range of 0.45-0.75 mm and a unit weight of 160 grams per square meter. Another exemplary fabric is described in U.S. Provisional Patent Application Ser. No. 62/121,808, entitled, “Multipurpose Consumer Scrubbing Cloths and Methods of Making Same” filed Feb. 27, 2015, and incorporated by referenced herein in its entirety. An example foam useful with the present disclosure is a polyurethane foam having relatively non-porous top and bottom surfaces, commercially available under the trade designation of TEXTURED SURFACE FOAM, POLYETHER, M-100SF from Aearo Technologies, LLC, Newark, Del., USA. Exemplary sponges useful with the present disclosure are the cellulose sponges commercially available under the trade designations of SCOTH-BRITE Stay Clean Non-Scratch Scrubbing Dish Cloth having catalog number 9033-Q and SCOTH-BRITE Stay Clean Non-Scratch Scrub Sponge with a catalog number of 20202-12, both from 3M COMPANY, St. Paul, Minn., USA.

Nonwovens likewise can be formed from a variety of materials and in a variety of fashions selected to provide desired properties, such as extensibility, elasticity, etc., in addition to the requisite suppleness. In most general terms, a nonwoven is comprised of individual fibers entangled with one another (and optionally bonded) in a desired fashion. The fibers are preferably synthetic or manufactured, but may include natural materials such as wood pulp fiber. As used herein, the term “fiber” includes fibers of indefinite length (e.g., filaments) and fibers of discrete length (e.g., staple fibers). The fibers used in connection with a nonwoven substrate 12 may be multicomponent fibers. The term “multicomponent fiber” refers to a fiber having at least two distinct longitudinally coextensive structured polymer domains in the fiber cross-section, as opposed to blends where the domains tend to be dispersed, random, or unstructured. The distinct domains may thus be formed of polymers from different polymer classes (e.g., nylon and polypropylene) or be formed of polymers of the same polymer class (e.g., nylon) but which differ in their properties or characteristics. The term “multicomponent fiber” is thus intended to include, but is not limited to, concentric and eccentric sheath-fiber structures, symmetric and asymmetric side-by-side fiber structures, island-in-sea fiber structures, pie wedge fiber structures, and hollow fibers of these configurations. In addition to the availability of a wide variety of different types of fibers useful for a substrate 12, the technique for bonding the fibers to one another is also extensive. In general terms, suitable processes for making the nonwoven substrate 12 that may be used in connection with the present disclosure include, but are not limited to, spunbond, blown microfiber (BMF), thermal bonded, wet laid, air laid, resin bonded, spunlaced, ultrasonically bonded, etc. In an embodiment, the substrate 12 is spunlaced utilizing a fiber sized in accordance with known spunlace processing techniques. With this manufacturing technique, one construction of a nonwoven substrate 12 is a blend of 50/50 wt. % 1.5 denier polyester and 1.5 denier rayon at 50-60 g/m². The substrate 12 is first carded and then entangled via high-pressure water jets as is known in the art. The spunlace technique eliminates the need for a thermal resin bonding component, so that the resulting nonwoven substrate is amenable to being loaded with virtually any type of chemical solution (i.e., anionic, cationic, or neutral). An exemplary nonwoven includes a thermally point-bonded spunbond poly(ethylene terephthalate) nonwoven wipe.

Films, such as single layer or multi-layered polymer films made by extrusion, solvent casting, calendaring, stretching (e.g., via a tenter or stretching frame) and by other customary polymer processing method, are suitable for this invention. One exemplary film is a plastic film made of melt-extruded, biaxially oriented and primed poly(ethylene terephthalate), polyolefin films, elastomeric films made of physically and chemically crosslinked elastomers, films made of vinyl monomers, such as poly(vinyl chloride), poly(vinylidene chloride) (which is commonly known under the trade designation of ‘SARAN’ or ‘SARAN WRAP from S.C. Johnson & Son of Racine, Wis.), fluoropolymers, such as poly(vinylidene fluoride), silicones, polyurethanes, polyamides, poly(lactic acid), and combinations thereof.

Other fabrics, sponges, foams, films, wovens and nonwovens are likewise contemplated and these examples are not meant to be limiting. Regardless of the exact construction, however, the substrate 12 is highly conducive to handling by a user otherwise using the article 10 for scrubbing purposes and is selected having regard to the intended use of the scrubbing article 10.

Although the substrate 12 is depicted in the cross-sectional view of FIG. 2 as a single layer structure, it should be understood that the substrate 12 may be of single or multi-layer construction. If multi-layered construction is used, it will be understood that the various layers may have the same or different properties, constructions, etc., as is known in the art. For example, in one alternative embodiment, the substrate 12 is constructed of a first layer of 1.5 denier rayon and a second layer of 32 denier polypropylene. This alternative construction provides a relatively soft substrate, such that the resulting wiping article 10 is conducive for use cleaning a user's skin, akin to a facial cleansing wipe. The substrate 12 may also include additional layers, such as an adhesion promoter layer or a tie layer, for example.

### Texture Layer Compositions

As discussed above, the texture layer 14 is an abrasive composition that is imparted to substrate 12 and subsequently e-beam crosslinked or e-beam polymerized or both as will be described below. The exact composition of the texture layer 14 can vary depending upon desired end performance characteristics. To this end, a texture layer composition is initially formulated and then deposited or formed on the substrate 12. This composition will include a selected resin and may include additional constituents such as mineral(s), filler(s), colorant(s), thickener(s), defoaming agent(s), surfactant(s) etc. Regardless of the exact composition, however, the selected composition is e-beam treatable (i.e., polymerizable, crosslinkable) and imparts the desired features (e.g., manufacturability, scrubbiness, durability, hardness and abrasion resistance) to the scrubbing article 10. As a point of reference, the texture layer composition 14 may be described as “e-beam crosslinkable” or “e-beam polymerizable”, or both, prior to e-beam treatment (e.g., crosslinking, polymerization) of the deposited or formed (e.g., printed, coated, embossed, micro-replicated, etc.) texture layer 14 and as “e-beam crosslinked” or “e-beam polymerized”, or both, after the texture layer 14 has undergone e-beam treatment. The processes of depositing or forming and subsequently e-beam treating the texture layer compositions of the present disclosure are further discussed below. In addition, as defined herein, an interim scrubbing article 17 is formed after the texture layer composition 14 is provided on substrate 12 but prior to e-beam treatment of the composition 14 and will likewise be discussed in further detail below.

Various materials are suitable for forming the texture layer 14. As described above, texture layer 14 comprises a resin composition and may comprise various polymers and/or monomers. Some acceptable resins include those resins selected from the group consisting of polyolefins, styrene-butadiene resin, styrene-isoprene resin, acrylic resin, phenolic resin, nitrile resin, ethylene vinyl acetate resin, polyurethane resin, styrene-acrylic resin, vinyl acrylic resin and combinations thereof. Other non-limiting examples of binder resins useful with the present disclosure include amino resins, alkylated urea-formaldehyde resins, melamine-formaldehyde resins, acrylic resins (including acrylates and methacrylates) such as vinyl acrylates, acrylated epoxies, acrylated urethanes, acrylated polyesters, acrylated acrylics, acrylated polyethers, vinyl ethers, acrylated oils, and acrylated silicones, alkyd resins such as urethane alkyd resins, polyester resins, reactive urethane resins, phenolic resins such as resole and novolac resins, phenolic/latex resins, epoxy resins, and the like. The resins may be provided as monomers, oligomers, polymers, or combination thereof. Monomers may include multifunctional monomers capable of forming a crosslinked structure, such as epoxy monomers, olefins, styrene, butadiene, acrylic monomers, phenolic monomers, substituted phenolic monomers, nitrile monomers, ethylene vinyl acetate monomer, isocyanates, acrylic monomers, vinyl acrylic monomer and combinations thereof. Other non-limiting examples of binder resins useful with the present disclosure include amino acids, alkylated urea monomers, melamines, acrylic monomers (including acrylates and methacrylates) such as vinyl acrylates, acrylated epoxies, acrylated urethanes, acrylated polyesters, acrylated acrylics, acrylated ethers, vinyl ethers, acrylated oils, and acrylated silicones, alkyd monomers such as urethane alkyd monomers, and esters.

Polymeric materials especially useful with the present disclosure include those polymers that are known to have a tendency toward a dominant crosslinking reaction as opposed to a dominant degradation reaction when subjected to electron beam irradiation. Electron beam irradiation can cause both degradation (reduction of molecular weight) and crosslinking reactions in materials. Depending upon the rate of each of these reactions with respect to one another, one or the other (degradation or crosslinking) will be the dominant reaction. For example, polyethylenes can have faster and therefore more dominant crosslinking reactions when subjected to e-beam irradiation, and thus may be especially useful with the present disclosure. Conversely, polypropylenes may have faster degradation reactions and therefore it may be more difficult to achieve the desired crosslinking in these compositions undergoing e-beam irradiation. For some compositions, little to no effect is achieved upon an initial exposure to e-beam irradiation, however, repeated exposure may provide a reaction in these compositions. An example of materials that are less likely to either degrade or crosslink when exposed to e-beam radiation is a polyethylene terephthalate or, PET. It is to be understood, however, that these designations are not meant to be limiting and for example, polypropylene polymers as well as PET based polymers may be used in texture layer compositions 14 according to some embodiments of the present disclosure. An exemplary polymeric material useful in forming texture layer 14 is available, for example, from Mallard Creek Polymers, Inc., Charlotte, N.C., USA under the trade designation ROVENE 5900. As described, the particular materials and weight percent relative to the texture layer composition may be chosen to satisfy the desired end application requirements.

Other desirable features of texture layer 14 compositions include compositions having a molecular weight and/or viscosity that allows for the e-beam treatable texture layer 14 to have sufficient (e.g., minimum level of) adhesion to the substrate 12 to which it is applied such that it does not readily wipe off of or shift along the substrate surface 16 (i.e., such that the texture layer 14 stays on the substrate surface 16 after transfer of the texture layer 14 to the substrate 16 and prior and/or subsequent to e-beam treatment). Further, the texture layer 14 desirably has a molecular weight resulting in qualities (e.g., hardiness, stability etc.) at room temperature such that, after application to a substrate (e.g., 12) it does not stick to itself or deform readily when contacted, for example if the interim substrate 17 is wound upon itself to be further processed (e-beam treated) offline at a location different from the printing location, such as further discussed below. To this end, suitable materials for the texture layer 14 composition may also be selected to have molecular weights and/or viscosities resulting in desired material flow properties. Specifically, materials may be selected to have molecular weights or viscosities allowing the texture layer 14 composition to be flowable in a manner that will fill the holes or voids of stencil pattern during transfer or printing of the composition to a substrate 12, sufficiently adhere to the substrate 12 and to hold the desired pattern shape upon removal of the stencil from the substrate 12, even prior to (though especially subsequent to) additional processing such as rest or wait periods, heat treatment (evaporation) or e-beam treatment. The viscosity of a texture layer 14 composition may be selected to provide a sharp pattern.

In addition, the composition of the texture layer 14 notably may be formulated without a thermal or UV crosslink-initiating component and in this manner is characterized by the absence of thermal or UV crosslink-initiator. Formulating the texture layer 14 without an initiator can be advantageous in that, for compositions lacking an initiator, no undesired residue (e.g, chemicals) will be present before, during and after e-beam treatment (e.g., crosslinking, polymerization) of the composition in contrast to thermal and UV crosslinkable compositions. Initiators used in thermal crosslinking and photoinitiators used in UV crosslinking processes can leave undesirable residual materials that in some cases can leech out of the composition. Despite the advantageous nature of compositions which can be e-beam treated without initiators present, it is to be understood that an initiator, a promoter, or a retardant can optionally be provided as part of the formulation or composition of texture layer 14, according to some embodiments of the present disclosure, as described in detail in textbooks such as Radiation Processing of Polymers (chapter 6), edited by A. Singh and J. Silverman and in Radiation Technology for Polymers (chapter 5) by J. G. Drobny. Some initiators and promoters that can assist e-beam crosslinking or e-beam polymerization, or both, include solvents, such as methanol, ethanol, n-butanol, n-octanol, dimethylformamide, dimethylsulfoxide, acetone, and 1,4-dioxane; acids, such as acetic acid, formic acid, perchloric acid, and sulfuric acid; salts, such as lithium perchlorate; monomers, such as divinylbenzene and trimethylolpropane triacrylate; halogenated compounds, such as iodo-, chloro-, bromo-substituted aliphatic and aromatic compounds; nitrous oxide; sulfur monochloride; maleimides; thiols (polymercaptans), such as dodecanethiol, dimercaptodecane, dipentene dimercaptan, and trimethylolpropane trithioglycolate; acrylic and allylic compounds, such as tetramethyl diacrylate and ethylene dimethacrylate. These initiators can expedite the crosslinking and polymerization processes and may optionally be desired, for example, in cases where the rate of the crosslinking/polymerization is relatively slow without the initiator or as compared to other e-beam crosslinkable or polymerizable compositions. In some embodiments, the composition of the texture layer further includes a retardant, as described in detail in textbooks such as in Radiation Technology for Polymers (chapter 5) by J. G. Drobny. Some retardants that can delay, prevent, or reduce the rate of e-beam crosslinking or e-beam polymerization, or both, include aromatic amines, quinines, aromatic hydroxyl sulfur, aromatic nitrogen compounds, and N-phenyl-beta-naphtylamine.

In some embodiments, the texture layer 14 optionally further includes a particulate additive for enhanced hardness. To this end, and as described in greater detail below, the scrubbing article 10 of the present disclosure is useful in a wide variety of potential applications having different scrubbing requirements. For some applications, it is desirable that the scrubbing article 10, and in particular the texture layer 14, be more or less abrasive than others. While the above-described resin component of the texture layer 14 independently imparts a scrubbiness feature to the article 10 greater than other available scrubbing articles, this scrubbiness characteristic can be further enhanced via the addition of a particulate component. With this in mind, a wide variety of minerals or fillers as known in the art can be employed. Useful minerals include A_{l2O3}, “Minex” (available from The Cary Co. of Addison, Ill.), Si_{O2}, Ti_{O2}, etc. Exemplary fillers include CaC_{O3}, talc, etc. Where employed, the particulate component additive comprises less than 70% by weight of the texture layer 14, more preferably less than 50% by weight, most preferably less than 30% by weight. Further, the particulate component may consist of inorganic, hard, and small particles. For example, the “Minex” mineral particulate component has a median particle size of 2 microns and a Knoop hardness of about 560. Of course, other particle size and hardness values may also be useful. The inorganic nature of the particulate component, in conjunction with the non-ionic resin component, renders the resulting texture layer 14 amenable for use with any type of chemical solution.

The texture layer 14 can further include a colorant or pigment additive to provide a desired aesthetic appeal to the wiping article 10. Appropriate pigments are well known in the art, and include, for example, products sold under the trade name SUNSPERSE, available from Sun Chemical Corp. of Amelia, Ohio. Other coloring agents as known in the art are equally acceptable and in some embodiments comprise less than 10% of the texture layer composition by weight.

Additionally, the texture layer composition can include a thickening agent or agents to achieve a viscosity most desirable for the particular printing technique employed and speed of the manufacturing line. In this regard, appropriate thickening agents are known in the art and include, for example, methylcellulose and a material available under the trade name “RHEOLATE 255” from Rheox, Inc. of Hightstown, N.J. Another acceptable thickening agent is available from Huntsman International LLC, High Point, N.C., USA under the trade designation of LYOPRINT PT-XN. A thickening agent may be unnecessary depending upon the selected resin and printing technique; however, where employed, the thickening agent preferably comprises less than approximately 40% by weight of the texture layer composition. In other embodiments, a salt component may be provided in the composition to aid in causing an ionic reaction between components of an emulsion and thereby likewise generate an increase in the viscosity of the composition, as is known in the art. Notwithstanding the above, the composition of texture layer 14 may be non-ionic, according to some embodiments.

As indicated above, anti-foaming agents may be included in the composition to provide defoaming or emulsification of the composition. As described in Ullmann's Encyclopedia of Industrial Chemistry (section “Foams and Foam Control”), some anti-foaming materials are carrier oils; such as water-insoluble paraffinic and naphthenic mineral oils, vegetable oils, tall oil, castor oil, soybean oil, peanut oil; silicone oils, such as dimethylpolysiloxanes; hydrophobic silica; Hydrophobic fat derivatives and waxes, such as fatty acid esters of monofunctional and polyfunctional alcohols, fatty acid amides and sulfonamides, paraffinic hydrocarbon waxes, ozokerite, and montan wax, phosphoric acid mono-, di-, and triesters of short- and long-chain fatty alcohols, short- and long-chain natural or synthetic fatty alcohols, water-insoluble soaps of long-chain fatty acids, including aluminum stearate, calcium stearate, and calcium behenate, perfluorinated fatty alcohols; water-insoluble polymers, such as low molecular mass, fatty acid modified alkyd resins, low molecular mass novolaks, copolymers of vinyl acetate and long-chain maleic and fumaric acid diesters, and methyl methacrylate-vinylpyrrolidone copolymers, poly(propyleneglycols) and high molecular mass propylene oxide adducts to glycerol, trimethylol, propane (1,1,1-tris(hydroxymethyl)propane), pentaerythritol, triethanolamine, dipentaerythritol, polyglycerol, addition products of butylene oxide or long-chain a-epoxides with polyvalent alcohols. An example anti-foaming agent is a silicone emulsion commercially available under the trade designation of XIAMETER AFE-1520, manufactured by Dow Corning Corporation of Midland, Mich., USA.

In some embodiments, the composition of the texture layer 14 may include binder resins, ceramic microparticles or processing agents as described in U.S. Provisional Patent Application Ser. No. 62/121,644, entitled, “Consumer Scrubbing Article with Ceramic Microparticles and Method of Making Same” filed on Feb. 27, 2015 and incorporated by referenced herein in its entirety.

Finally, and as previously described, the scrubbing article 10 of the present disclosure can be used “dry” or can be loaded with a chemical (solution or solid). The term “loaded” is in reference to a chemical solution being absorbed by the substrate 12 prior to being delivered to a user. In addition or alternatively, the chemical may be sprayed onto a surface of the cloth. In still further embodiments, a chemical may be provided in or as part of the texture layer composition 14. Thus, deposited (e.g., printed) texture layer 14 may comprise printed soap scrubbing dots (e.g., 20a, 20b, FIG. 3). With these various constructions, during use, the chemical solution is released from the substrate 12 as the user wipes the scrubbing article 10 across a surface. Thus, in embodiments where the chemical is provided as part of the texture layer 14, the texture layer (i.e., scrubbing portions 20a, 20b) may gradually decrease in size as the chemical is consumed during a scrubbing application. When texture layer 14 is of a non-ionic nature, virtually any desired chemical can be used, including water, soap, quaternary ammonium salt solutions, Lauricidin™-based anti-microbials, alcohol-based anti-microbials, citrus-based cleaners, solvent-based cleaners, cream polishes, anionic cleaners, amine oxides, etc. That is to say, where employed, the chemical solution can be anionic, cationic, or neutral.

### Formation of the Scrubbing Article

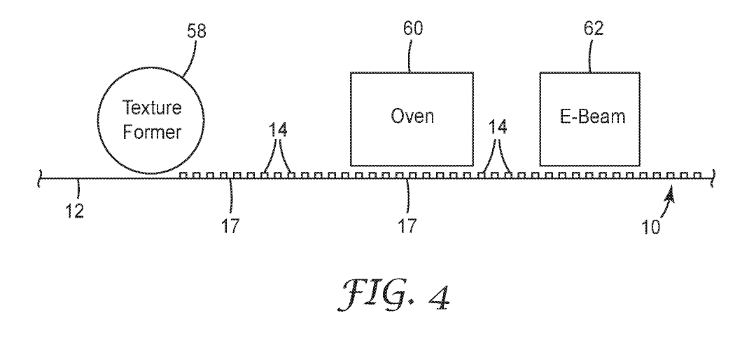

Manufacture or formation of the scrubbing article 10 of the present disclosure is depicted in the simplified form of FIG. 4 and generally includes formulating the appropriate texture layer composition, imparting the composition to the substrate 12 (e.g., via printing, coating, etching, embossing, molding, micro-replicating, etc.), and then e-beam treating the deposited or formed composition, thereby resulting in an e-beam crosslinked or e-beam polymerized (or both) texture layer 14. Various techniques for actual depositing or imparting of the composition 14 to the substrate 12 are described below. Importantly, however, and as noted above, the texture layer composition is formulated such that constituents may be e-beam crosslinked and/or e-beam polymerized as part of the e-beam treating step. This represents distinct advantages over other techniques used to form a scrubbing article having a textured surface.

Prior to forming a texture layer 14 on a substrate 12, depending upon the type of substrate, the surface 16 of the substrate 12 may be primed. Priming may involve mechanical, chemical, physical and material application methods. For example, some surface priming methods that may be especially useful with the present disclosure include consolidating one side of a substrate with the use of heat and/or pressure, flame treating/melting, cutting or removing fiber height such as described in U.S. Provisional Patent Application Ser. No. 62/121,808, entitled, “Multipurpose Consumer Scrubbing Cloth and Method of Making Same” filed on Feb. 27, 2015 and incorporated by referenced herein in above. Alternatively, priming may include application of a chemical primer such as an adhesive. Notably, however, for many substrates 12, no primer is necessary prior to transfer of the texture layer 14 composition onto the substrate 12 and achieve adequate adhesion.

The texture layer 14 composition can be formed on the substrate 12 using a variety of known techniques such as printing, (e.g., screen printing, gravure printing, flexographic printing, etc.), coating (e.g., roll, spray, electrostatic), etching, laser etching, injection molding, micro-replicating, and embossing. In general terms, and with reference to FIG. 4, texture former (of various types) 58 deposits or imparts an e-beam crosslinkable and/or e-beam polymerizable texture layer 14 onto substrate 12 in any desired pattern, such as any of the various patterns described above. The texture former 58 can include, for example, a printer, roll coater, spray coater, etching device, laser, embossing equipment, etc. As one specific, non-limiting example, use of a printing method for imparting the texture layer 14 to the substrate 12 may be advantageous in that printing techniques can provide a relatively high-definition (e.g., sharp) printed composition 14. Some printing techniques may also afford relative ease of manufacture and lower cost as compared to other texture forming techniques described above. Regardless of the texture forming technique, as previously described, the texture layer 14 covers less than an entirety of the nonwoven substrate surface to which it is transferred (i.e., the surface 16 of FIG. 2), and is preferably formed in a pattern including two or more discrete sections. In this regard, a wide variety of patterns can be provided. For example, the pattern can consist of a plurality of dots as shown in FIG. 1. Alternatively, the lines can be connected to one another. In yet alternative embodiments, and with additional reference to FIGS. 5A-5B, the texture layer consists of a plurality of discrete lines, dots, and/or images. Further, other desirable pattern components, such as a company logo, can be formed. Alternatively, a more random distribution of texture layer sections can be imparted to the substrate 12. The present disclosure contemplates that virtually any pattern can be obtained.

Once the texture layer 14 is formed on the substrate 12, but prior to exposure to e-beam radiation (as discussed below), an interim scrubbing article 17 is formed. The interim scrubbing article 17 is characterized as having an e-beam treatable (i.e., e-beam crosslinkable and/or e-beam polymerizable) texture layer 14 that has not yet undergone e-beam treatment (i.e., the e-beam radiation exposure step has not yet been performed). The interim scrubbing article 17 may thus also be referred to as an interim textured scrubbing article 17. Regardless, the interim scrubbing article 17 may next be allowed to remain undisturbed (allowed to wait) for a period of time or may directly or immediately proceed to an optional water evaporation step. For various texture layer 14 compositions described above, excess water may be present in the resin formulation. For example, the texture layer 14, just after transfer to the substrate 12, may contain as much as 40-50%, or more water. In some embodiments, the retained water may cause texture layer 14 to lack a desired stability on the substrate 12 (i.e., the texture layer 14 may be subject to damage or alteration such as by contact with another object, a person or other surface of the article, e.g., if the interim scrubbing article 17 is wound upon itself) and a desired level of adhesion to the substrate 12. Also, the water content in the deposited (formed) texture layer 14 may impart an undesirable “tackiness” characteristic to the deposited texture layer 14. As defined herein, “tackiness” means slightly adhesive, gummy or sticky to the touch. Therefore, the interim scrubbing article 17 may undergo an optional water evaporation step whereby the article 17 is exposed to heat, such as given by an oven (60, FIG. 4) or infrared light (not shown), for a short period of time. Oven and/or infrared light exposure times may vary and may for example be in a range of less than 5 minutes, 3 minutes or less, or 2 minutes or less. With regard to infrared exposure, often infrared light exposure is more cost effective than heating via an oven. However, unless the composition of material undergoing infrared light exposure is naturally highly absorbing of infrared light, an additive may be required to allow absorption of the infrared light by the composition. An example of an additive useful for aiding in infrared absorption is carbon black. Regardless, the water evaporation step can facilitate a stronger or more desirable adherence of the texture layer 14 to the substrate surface 16 and can provide a more stable, less tacky texture layer 14. It is to be understood that subjecting the texture layer 14 to the electron beam itself can likewise evaporate water present in the texture layer 14 composition such that the evaporation step (heat or infrared treatment) is unnecessary. However, in cases where residual water is present in the texture layer 14, it may be desirable to evaporate off a quantity of residual water from the composition 14 prior to the e-beam treatment step since water evaporation within the electron beam unit (e.g., 62, FIG. 4) can interfere with or cause eventual degradation of the electron beam apparatus 62. Likewise, it is to be understood that for some compositions of texture layer 14, no excess water is present in the texture layer 14 prior to e-beam treatment, thus no evaporation step may be desired or necessary. For example, in embodiments of the present disclosure, the texture layer composition 14 comprises a molten polymeric material that does not require a water based resin or compound to achieve material flow sufficient to transfer to a substrate (e.g., 12) in a desired pattern. Rather, as extruded, the molten polymeric material can be deposited (e.g., printed, coated etc.) directly onto a substrate 12. The molten polymer material may flow under pressure to the substrate 12 and then cool and solidify on the substrate 12 to form the texture layer 14.

Notably and advantageously, the interim scrubbing article 17, either prior or subsequent to the wait period and/or the evaporation step, may be formed into a roll (a rolled interim article 17 and roll-forming step are not shown) in a manner of material winding as is known in the art. As described above, the composition forming texture layer 14 may have a molecular weight and/or viscosity that advantageously allows for this type of roll-forming prior to e-beam treatment of the deposited texture layer 14. Next, after the texture layer 14 has been formed on the substrate 12, and after any or all of the optional wait period, evaporation, or roll-forming steps described above, the interim textured scrubbing article 17 is subjected to e-beam radiation to crosslink or polymerize, or both, the texture layer 14 composition provided thereon. As illustrated in FIG. 4, an e-beam 62 irradiates e-beam treatable texture layer 14 of interim scrubbing article 17 to thereby form an e-beam treated (i.e., e-beam crosslinked and/or e-beam polymerized) texture layer 14 on substrate 12 thus forming the resultant scrubbing article 10. Due to the stable nature or chosen viscosity of the texture layer 14 composition, the e-beam treatable texture layer 14 and the e-beam treated texture layer 14 will have a substantially similar or a same texture pattern i.e., the pattern created by the initial deposition or formation of texture layer 14 will not substantially change, if at all, prior to or after e-beam treatment of the texture layer 14.

As described, e-beam treatment provides all of the advantages of crosslinking and polymerization such as durability, solvent and chemical resistance, tensile and impact strength, abrasion resistance, and environmental stress crack resistance, while having none of the disadvantages of other crosslinking techniques including residual chemicals and longer cure periods. In addition, in a UV crosslinking process, resin compositions can include relatively lower molecular weight liquids than compositions that may be applied to a substrate and e-beam crosslinked. The higher molecular weight materials that are possible in an e-beam treatment allow for a sufficiently stable/durable formed texture layer 14 that may be rolled and processed further at a later time or location (i.e., offline), as described above.

Regardless of the exact composition and dimensions of substrate 12 and the composition, dimensions or pattern of the texture layer 14, the scrubbing article 10 of the present disclosure provides a marked improvement over previous consumer scrubbing articles in terms of cost as well as ease and flexibility of the manufacturing processes that may be used in forming scrubbing articles. In addition, scrubbing articles of the present disclosure exhibit suitable abrasion resistance performance and may beneficially include a texture layer 14 devoid of residual chemicals. Likewise, e-beam crosslinked texture layers 14 of the present disclosure may have increased durability, hardness, tensile and impact strength, high-heat properties, solvent and chemical resistance, and environmental stress crack resistance. Exemplary scrubbing articles 10 are provided below. The components and/or weight percent amounts provided by the compositions can readily be varied, yet fall within the scope of the present disclosure.

### Examples

TABLE 1
Texture Layer (Printing Abrasive) Materials

| Item | Description |
|---|---|
| Latex | Carboxylated styrene-butadiene emulsion with a |
| | Brookfield viscosity of 200 cps (#2/20 rpm) and pH of |
| | 9.0, commercially available under the trade designation |
| | ROVENE 5900 from MALLARD CREEK POLYMERS, |
| | INC., Charlotte, NC, USA. |
| Pigment | Liquid white pigment with a density of 1.984 g/cc, |
| | commercially available under the trade designation of |
| | WHD9507 SUNSPERSE WHITE 6, from SUN CHEMICAL |
| | CORPORATION, Cincinnati, OH, USA |
| Thickener | Fully neutralized, anionic acrylic polymer dispersion |
| | with a specific gravity of 1.1, commercially available |
| | under the trade designation of LYOPRINT PT-XN from |
| | HUNTSMAN INTERNATIONAL LLC, High Point, North |
| | Carolina, USA |
| Silicone | Silicone emulsion with a specific gravity of 1.0 and |
| Emulsion | with a pH of 3.5, commercially available under the |
| | trade designation of XIAMETER AFE-1520, from DOW |
| | CORNING CORPORATION, Midland, MI, USA. |

### Preparation of Texture Layer Compositions

All ingredients from TABLE 1 were weighed out to the nearest 0.1 grams in separate plastic containers in desired quantities. A mixture was prepared by placing all ingredients in a rigid plastic container. A plastic lid was secured on the container before starting the mixing. The mixture was mixed for 30 seconds in a laboratory centrifugal mixer commercially available from Flaktek, Inc., Landrum, S.C., USA under the trade designation of SPEEDMIXER DAC 400.1 VAC-P. After 30 seconds, the mixer was stopped, and the plastic container which had the mixture in it was removed the mixer. The container was left undisturbed on a laboratory bench for 24 hours. The composition of the resultant e-beam crosslinkable texture layer (printing abrasive) mixture is presented in TABLE 2.

TABLE 2
Composition of the Prepared Mixture

| Component | Composition (grams) |
|---|---|
| Latex | 95 |
| Pigment | 3 |
| Silicon Emulsion | 0.2 |
| Thickener | 1.8 |
| TOTAL | 100 |

TABLE 3
Substrate Materials

| | |
|---|---|
| Plastic | Melt extruded, biaxially oriented and primed |
| Film | poly(ethylene terephthalate) film with a thickness |
| | of 0.13 mm |
| Non-woven | Thermally point-bonded spunbond poly(ethylene |
| wipe | terephthalate) non-woven wipe with a unit weight of |
| | 70 grams/m². |
| Foam | Polyurethane foam sheet with a density of 27 kg/m³, |
| | with a thickness of 2.54 cm, and with a relatively |
| | non-porous top and bottom surfaces, commercially |
| | available under the trade designation of TEXTURED |
| | SURFACE FOAM, POLYETHER, M-100SF from AEARO |
| | TECHNOLOGIES LLC, Newark, DE, USA. |
| Cellulose | Cellulose sponge sheet commercially available under |
| Sponge | the trade designation of SCOTCH-BRITE STAY CLEAN |
| | SCRUBBING DISH CLOTH with a catalog number of |
| | 9033-Q from 3M COMPANY, St. Paul, MN |
| Fabric | A knitted fabric prepared from 82% poly(ethylene |
| | terephthalate) and 18% polyamide 6 fibers which has |
| | a thickness in the range of 0.45-0.75 mm and which |
| | has a unit weight of 160 grams per square meter. |

### Preparation of the Substrate Materials

A rectangular specimen of each of the five substrate materials (film, non-woven wipe, foam, cellulose sponge, and fabric) described above in TABLE 3, with approximate dimensions of 30 cm×20 cm, was obtained. Each specimen was, in turn, secured on a flat laboratory bench by applying adhesive tape on its edges for subsequent printing of the prepared composition (described in TABLE 2) thereon.

Printing the Prepared Compositions onto the Prepared Substrates

For each of the prepared substrates of TABLE 3, a metal stencil with the texture pattern shown in FIG. 1 was placed on top of the substrate specimen. Approximately 100 grams of the prepared printing composition was placed on the stencil with the help of a wooden applicator. The printing mixture was then applied on the printing pattern of the stencil with a shearing motion while applying hand pressure downwards and with the help of a hand-held squeegee. It was observed that for each specimen, the printing mixture filled the holes of the printing pattern and was transferred onto the substrate specimen. Then, the stencil was removed and the printed substrate specimen was left undisturbed on a laboratory bench for 10 minutes.

It was determined that the properties of the printing mixture of TABLE 2 played an important role in the printing operation. For example, it was determined that if a printing mixture with a very low viscosity (such as approximately 100 cps at 25° C.) was printed on a substrate, it was not possible to obtain a sharp printed pattern. With these low viscosity mixtures, the printed droplets almost immediately coalesced on the substrate and formed a continuous film, instead of discreet droplets. It was estimated that the minimum viscosity for the particular printing mixture described should be on the order of 1000 cps, determined at 25° C. for proper printing. The printing mixture described herein had a high enough viscosity to allow proper printing. It is to be understood that other viscosities are likewise contemplated and the exact viscosity of the composition may vary, while still achieving acceptable performance, depending upon the composition of the mixture used.

After 10 minutes, the printed specimen was placed in a laboratory hot air circulating oven (Model VRC2-35-1E, commercially available from Despatch Industries, Minneapolis, Minn., USA) for 3 minutes. The temperature of the oven was set to 149° C. After 3 minutes, the printed specimen was taken out of the oven and left was left undisturbed on a laboratory bench for 24 hours.

### E-Beam Treatment of the Printed Samples

After 24 hours, the printed nonwoven specimen was rolled upon itself and transported to an e-beam processing line. The film, foam and cellulose sponge samples were not rolled and instead were transported in unrolled form in a closed container. The printed samples were then subjected to electron beam (e-beam) radiation to effect e-beam crosslinking of the printed texture composition. The printed plastic film, cellulose sponge, non-woven wipe, and fabric substrates were subjected to e-beam radiation in a continuous line (ElectroCurtain®, Energy Sciences, Inc. (ESI), Wilmington, Mass., USA), which was operated at a line speed of 6 m/s and at a voltage of 300 kV. The radiation levels were varied between 4-20 Mrad. The specimens passed under the e-beam only once. The printed foam specimens were subjected to e-beam radiation in a continuous line (EC-series, PCT Engineered Systems, Davenport, Iowa, USA), which was operated at a line speed of 7.6 m/s and at a voltage of 295 kV. The radiation levels were varied between 4-20 Mrad. The specimens passed under the e-beam only once.

### Abrasion Resistance Testing Procedure for the Printed Samples

The abrasion resistance of the printed specimens was tested by rubbing a hand-held scouring pad (commercially available under the trade designation of EXTREME SCRUB HAND PAD from 3M COMPANY, St. Paul, Minn., USA) onto the samples with the hand pressure. Each tested specimen was placed on a flat laboratory bench and secured onto the bench by applying adhesive tape on its corners. The scouring pad was thoroughly washed under running tap water and squeezed by hand 5 times to remove any excess water absorbed by the pad. Then, the scouring pad was rubbed back and forth on the specimen by only applying slight hand pressure with a shearing motion. The combination of each back and forth motion was considered to form a cycle. Each specimen was visually observed after 20 cycles and the extent of abrasion resistance was evaluated, as described in TABLE 4, below.

TABLE 4
Evaluation of Abrasion Resistance of
E-beam Crosslinked Printed Samples

| Strength of | |
|---|---|
| abrasion | |
| resistance | Description |
| 9 | The printed pattern was only slightly abraded after |
| | 20 cycles. Most of the printed pattern stayed intact |
| | on the substrate or the substrate was worn off before |
| | the pattern did (cohesive failure). |
| 3 | The printed pattern showed a certain level of abrasion |
| | resistance. The pattern did not easily wear off, however |
| | it was still possible to remove it from the substrate. |
| | No cohesive failure was observed. |
| 1 | The printed pattern did not show significant abrasion |
| | resistance. The pattern was abraded with relative ease. |

### Results

The abrasion resistance of the printed specimens is presented in TABLE 5. The results indicate that the e-beam treatment was especially advantageous for the mixture printed on the non-woven substrate as compared to the non-woven not receiving e-beam treatment. E-beam treatment appeared to show acceptable abrasion resistance for each of the film, fabric, non-woven and foam samples. It was apparent that the cellulose sponge showed an average performance. Although not being bound by any theoretical consideration, it is contemplated that the average performance of the cellulose sponge may have resulted from a lack of substantial extent of functional chemical groups on the cellulose sponge surface which in turn limited the extent of interfacial bonding between the cellulose sponge and the printed compositions.

TABLE 5
Abrasion Resistance of the Printed Samples

| | Substrate | | | | |
|---|---|---|---|---|---|
| Radiation | Plastic | | Non- | | Cellulose |
| Dose (Mrad) | film | Fabric | woven | Foam | Sponge |
| 0 | 9 | 9 | 3 | 9 | 1 |
| 4 | 9 | 9 | 9 | 9 | 1 |
| 8 | 9 | 9 | 9 | 9 | 1 |
| 12 | 9 | 9 | 9 | 9 | 1 |
| 20 | 9 | 9 | 9 | 9 | 1 |

As discussed above, e-beam irradiation can be costly which may be a contributing factor in the lack of development to date of an e-beam treated textured surface on a scrubbing article. However, the present disclosure surprisingly shows that e-beam crosslinked and/or e-beam polymerized compositions on various substrates can form scrubbing articles having advantageous manufacturing and performance attributes despite these high equipment costs. The flexibility and speed of manufacture may mitigate some of the costs associated with the e-beam equipment investment.

Although the present disclosure has been described with reference to preferred embodiments, workers skilled in the art will recognize that changes can be made in form and detail without departing from the spirit and scope of the present disclosure.

What is claimed is:

1. A scrubbing article comprising:
a substrate including a material selected from the group consisting of a woven, non-woven, knit, fabric, foam, film and sponge or combinations thereof;
wherein the substrate includes a surface comprising an e-beam treated texture layer.

2. The scrubbing article of claim 1, wherein the texture layer defines a pattern.

3. The scrubbing article of claim 2, wherein the pattern includes a plurality of discrete segments.

4. The scrubbing article of claim 1, wherein the texture layer extends at least 500 microns outwardly from the surface of the substrate.

5. The scrubbing article of claim 1, wherein the texture layer is characterized by the absence of a thermal and a photo-initiating component.

6. The scrubbing article of claim 1, wherein the texture layer includes a plurality of randomly distributed texturings.

7. The article of claim 1, wherein the texture layer comprises an e-beam crosslinked texture layer.

8. The article of claim 1, wherein the texture layer comprises an e-beam polymerized texture layer.

9. The scrubbing article of claim 1, further comprising:
a chemical solution absorbed into the substrate.

10. The scrubbing article of claim 1, wherein the texture layer comprises a hardness that is at least equal to a hardness of the substrate.

11. The scrubbing article of claim 1, wherein the texture layer comprises a hardness that is equal to or greater than a hardness of the substrate.

12. The scrubbing article of claim 1, wherein the article is drapable.

13. The scrubbing article of claim 1, wherein the texture layer comprises a multiplicity of ceramic microparticles.

14. A method of manufacturing a scrubbing article comprising:
transferring a resin composition onto a surface of a substrate to form an e-beam treatable texture layer on the surface and thereby form an interim scrubbing article; and
treating the interim scrubbing article with e-beam radiation to form an e-beam treated texture layer on the substrate surface;
wherein the substrate comprises any of a woven, non-woven, fabric, knit, foam, film and sponge material.

15. The method of claim 14, wherein the e-beam treated texture layer comprises an e-beam crosslinked texture layer or an e-beam polymerized texture layer having a relative hardness that is at least equal to a hardness of the substrate.

16. The method of claim 14, wherein the e-beam treatable texture layer and e-beam treated texture layer each define a pattern that is substantially similar both prior to and subsequent to treating the interim scrubbing article with e-beam radiation.

17. The method of claim 14, wherein the method of manufacture is characterized by the absence of a thermal and a UV crosslinking step.

18. The method of claim 14, further comprising:
prior to the treating step, exposing the interim scrubbing article to heat to evaporate an amount of water from the e-beam treatable texture layer.

19. The method of claim 14, wherein the texture layer comprises a multiplicity of ceramic microparticles.

20. A method of forming an abrasive layer on a scrubbing article, the method comprising:
depositing an e-beam crosslinkable composition onto a surface of a substrate to form an e-beam crosslinkable printed abrasive layer; and
e-beam crosslinking the printed abrasive layer by exposing the crosslinkable printed abrasive layer to e-beam radiation to form an e-beam crosslinked printed abrasive layer;
wherein the substrate has a flexibility greater than the flexibility of the e-beam crosslinked printed abrasive layer.
